(19) United States
(12) Patent Application Publication
(10) Pub. No.: US 2004/0011465 A1
(43) Pub. Date: Jan. 22, 2004

(54) Plasma Processing apparatus

(75) Inventors: Naoki Matsumoto, Nirasaki-shi (JP); Chishio Koshimizu, Nirasaki-shi (JP); Toshiaki Hongoh, Nirasaki-shi (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Tokyo (JP)

(21) Appl. No.: 10/618,603

(22) Filed: Jul. 15, 2003

(30) Foreign Application Priority Data
Jul. 16, 2002 (JP) 2002-207310

(51) Int. Cl. H01L 21/306

(52) U.S. Cl. 156/345.41

(57) ABSTRACT

A plasma processing apparatus for supplying microwaves into a process chamber so as to generate plasma, to thereby treat an object to be processed with the plasma. In the plasma processing apparatus, the process chamber has a top plate which is disposed opposite to the object to be processed, through the medium of a region for generating the plasma; and the top plate has at least one antenna which is disposed so that the antenna penetrates the top plate into the inside of the process chamber.

### BACKGROUND OF THE INVENTION

The present invention relates to a plasma processing apparatus which is suitably usable in a case where an object to be processed (such as substrate (or base material) for an electronic device) is plasma-treated for the purpose of manufacturing an electronic device, etc. More specifically, the present invention relates to a plasma processing apparatus which can generate a high-density plasma with high efficiency,

In general, the plasma processing apparatus according to the present invention is widely applicable to plasma processing of materials for electronic devices such as semiconductors or semiconductor devices, and liquid crystal devices.

### RELATED BACKGROUND ART

In recent years, as electronic devices, such as semiconductor devices, now have a higher density and a finer structure or configuration, in the processes for manufacturing these electronic devices, the number of cases wherein a plasma processing apparatus is used for conducting various kinds of processing or treatments such as film formation, etching, and ashing, have increased. When such a plasma processing is used, it is generally advantageous that a high-precision process control is facilitated in the process for manufacturing the electronic devices.

For example, as compared with the production of a semiconductor device (in this case, usually, the area to be processed is relatively small), the material to be processed (for example, a wafer) in the production of a liquid crystal device (LCD) has a larger diameter in many cases. Accordingly, when a plasma processing apparatus is used for the production of liquid crystal devices, the plasma to be used for the plasma processing is particularly required to be uniform and to have a high density over a large area.

Heretofore, CCP (capacitively coupled plasma)-type or parallel-plate plasma-type processing apparatuses and ICP (inductively coupled plasma) processing apparatuses have been used as the plasma processing apparatus.

Among these, in the case of the above CCP-type processing apparatus, there is generally used a process chamber having a pair of parallel plates, which has an Si top or ceiling plate, having a shower head structure for providing a uniform flow of a process gas, provided as the upper electrode constituting one of the pair of the above-mentioned parallel plates, and a susceptor which can apply a bias to the lower electrode as the other of the above pair of the parallel plates. In plasma processing, in this case, a substrate to be processed (an object to be processed) is placed on the susceptor, and plasma is caused to be generated between the above-mentioned upper electrode and lower electrode, so that the substrate is processed in a predetermined manner on the basis of the thus generated plasma.

However, in this CCP-type processing apparatus, as compared with other plasma sources, the resultant plasma density is relatively low and a sufficient ion flux is less liable to be obtained, so that the rate of the processing on the object to be processed (such as wafer) tends to be lower. In addition, even when the frequency of a power supply for providing electric power to the parallel plates is increased, a distribution in the electric potential appears in the electrode plane constituting the parallel plates and, accordingly, the resultant uniformity in the plasma and/or process is liable to be decreased. In addition, the consumption of the Si electrode is considerably heavy in the CCP-type processing apparatus and, accordingly, the resultant cost tends to become higher in view of the COC (Cost of Consumables) in this case.

On the other hand, in the above-mentioned ICP processing apparatus, in general, a turn coil to which a radio-frequency power is to be supplied is disposed on a dielectric top plate located in an upper portion of a process chamber (i.e., on the outside of the chamber), plasma is generated immediately below the top plate, on the basis of induction heating due to the coil, and the object to be processed is treated on the basis of the thus generated plasma.

In the conventional ICP processing apparatus, radio-frequency power is supplied to the turn coil disposed outside of the process chamber, to thereby generate plasma in the process chamber (that is, the supplied radio-frequency power generates plasma in the process chamber through the medium of the dielectric top plate). Accordingly, when the substrate (the object to be processed) is caused to have a larger diameter, a considerable mechanical strength must be imparted to the process chamber in view of vacuum sealing, the thickness of the dielectric top plate is inevitably increased and, accordingly, the resultant cost becomes higher. In addition, when the thickness of the dielectric top plate is increased, the transmission efficiency of the electric power from the turn coil to the plasma is decreased and, accordingly, the voltage for the coil is inevitably set to a higher value. As a result, the tendency that the dielectric top plate per se is subjected to sputtering is strengthened, and the above-mentioned COC becomes worse. Further, the foreign substance or contaminant which has been generated by this sputtering can be accumulated on the substrate, and the process performance can be worsened. In addition, as the turn coil per se is required to have a larger size, it becomes necessary to use a power supply of higher output so as to supply electric power to a coil having a larger size.

As described hereinabove, the prior art cannot realize a plasma processing apparatus which can generate high-density plasma with a high efficiency, particularly when an object to be processed having a larger area is to be treated for the purpose of producing a liquid crystal device, etc.

### SUMMARY OF THE INVENTION

An object of the present invention is to provide a plasma processing apparatus which has solved the above-mentioned problem encountered in the prior art.

Another object of the present invention is to provide a plasma processing apparatus which can generate high-density plasma with a high efficiency, even when an object to be processed having a larger area is to be treated.

As a result of earnest study, the present inventors have found that it is extremely effective, in solving the above-mentioned problem, to cause the chamber wall and/or top plate for defining a process chamber to have a specific configuration or structure, and to supply microwaves to the inside of the process chamber.

The plasma processing apparatus according to the present invention is based on the above discovery. More specifically, the present invention provides a plasma processing apparatus for supplying microwaves into a process chamber so as to generate plasma, to thereby treat an object to be processed with the plasma; wherein the process chamber has a top plate which is disposed opposite to the object to be processed, through the medium of a region for generating the plasma, and/or the process chamber has a chamber wall for defining the process chamber; and the top plate and/or chamber wall has at least one antenna which is disposed so that the antenna penetrates the top plate and/or chamber wall into the inside of the process chamber.

The present invention also provides a plasma processing apparatus for supplying microwaves into a process chamber so as to generate plasma, to thereby treat an object to be processed with the plasma; wherein the process chamber has a top plate which is disposed opposite to the object to be processed through the medium of a region for generating the plasma; and the top plate comprises a metal-based or silicon-based material.

The scope of the applicability of the present invention will become apparent from the detailed description given hereinafter. However, it should be understood that the detailed description and specific examples, while indicating preferred embodiments of the invention, are given by way of illustration only, as various changes and modifications within the spirit and scope of the invention will become apparent to those skilled in the art from this detailed description.

### BRIEF DESCRIPTION OF THE DRAWINGS

FIG. 1 is a schematic sectional view showing an embodiment of the plasma processing apparatus according to the present invention.

FIG. 2 is a schematic perspective view specifically showing an embodiment of the antenna arrangement in the plasma processing apparatus as shown in FIG. 1.

FIG. 3 is a schematic perspective view showing another embodiment of the antenna arrangement in the plasma processing apparatus as shown in FIG. 1,

FIG. 4 is a schematic perspective view specifically showing an embodiment of the antenna which is supported by one of the chamber walls in a cantilever state.

FIG. 5 is a schematic perspective view showing an embodiment of the antenna which is supported by both of the right and left chamber walls in a cantilever state.

FIG. 6 is a schematic perspective view showing an embodiment of the antenna which is supported by both of the right and left chamber walls so that the antenna penetrates the right and left chamber walls.

FIG. 7 is a schematic perspective view showing another embodiment of the antenna which is supported by both of the right and left chamber walls so that the antenna penetrates the right and left chamber walls.

FIG. 8 is a schematic perspective view showing a further embodiment of the antenna which is supported by both of the right and left chamber walls so that the antenna penetrates the right and left chamber walls.

FIG. 9 is a schematic sectional view showing an example of a top plate having a shower head structure.

FIG. 10 is a schematic perspective view showing an example of the plasma processing apparatus wherein the shape of the top plate has been changed.

FIG. 11 is a schematic perspective view showing another example of the plasma processing apparatus wherein the shape of the top plate has been changed.

FIG. 12 is a schematic perspective view showing a further example of the plasma processing apparatus wherein the shape of the top plate has been changed.

FIG. 13 is a schematic perspective view showing a further example of the plasma processing apparatus wherein the shape of the top plate has been changed.

FIG. 14 is a schematic perspective view showing an embodiment of the plasma processing apparatus according to the present invention wherein the distance between the top plate and the voltage-drawing (or voltage-introducing) rod has been changed.

FIG. 15 is a schematic perspective view showing another embodiment of the plasma processing apparatus according to the present invention wherein the distance between the top plate and voltage-drawing rod has been changed.

FIG. 16 is a schematic sectional view showing an embodiment of the plasma processing apparatus according to the present invention wherein a reflection-free terminator is provided on the termination of a microwave transmission line.

FIG. 17 is a schematic sectional view showing an embodiment of the plasma processing apparatus according to the present invention wherein a tuner capable of regulating the position of the voltage-drawing rod is provided.

FIG. 18 is a schematic sectional view showing another embodiment of the plasma processing apparatus according to the present invention wherein a tuner capable of regulating the position of the voltage-drawing rod is provided.

FIG. 19 is a schematic sectional view showing a further embodiment of the plasma processing apparatus according to the present invention wherein a tuner capable of regulating the position of the voltage-drawing rod is provided.

FIG. 20 is a schematic sectional view showing a further embodiment of the plasma processing apparatus according to the present invention wherein a tuner capable of regulating the position of the voltage-drawing rod is provided.

FIG. 21 is a partial schematic sectional view showing an embodiment of the plasma processing apparatus according to the present invention wherein a photoelectric sensor is provided in the process chamber.

FIG. 22 is partial schematic sectional view showing an embodiment of the plasma processing apparatus according to the present invention wherein an opening is provided on a grounded line in the process chamber.

FIG. 23 is partial schematic sectional view showing another embodiment of the plasma processing apparatus according to the present invention wherein an opening is provided on a grounded line in the process chamber.

### DETAILED DESCRIPTION OF PREFERRED EMBODIMENTS

Hereinbelow, the present invention will be described in detail with reference to the accompanying drawings, as desired. In the following description, “%” and “part(s)” representing a quantitative proportion or ratio are those based on mass, unless otherwise noted specifically.

### One Embodiment of Plasma Processing Apparatus

In the plasma processing apparatus according to the present invention, microwaves are supplied into a process chamber so as to generate plasma in the process chamber, to thereby treat an object to be processed. In an embodiment of the present invention, the top plate constituting the process chamber comprises a metal-based or silicon-based material. When the top plate is constituted by a metal-based material, at least the side of the top plate facing the inside of the process chamber is covered with an insulating substance.

When the top plate is constituted by a metal-based or silicon-based material in this manner, it becomes easy to cause the top plate to have a shower head structure (i.e., a structure wherein the top plate has a plurality of apertures or holes for passing a process gas therethrough). Accordingly, in this case, the partial pressure and/or composition, etc., of a reactant gas during the plasma treatment is made uniform due to the shower head structure, and therefore uniformity in the plasma treatment can further be enhanced.

Further, when the top plate is constituted by the metal-based material, the ignition of the plasma is facilitated on the basis of the capacitive coupling with the lower electrode, and the control of the drawing or introduction of the plasma is also facilitated.

On the other hand, when the top plate is constituted by a silicon-based material, the prevention of particulate material production is further facilitated.

### Antenna Arrangement

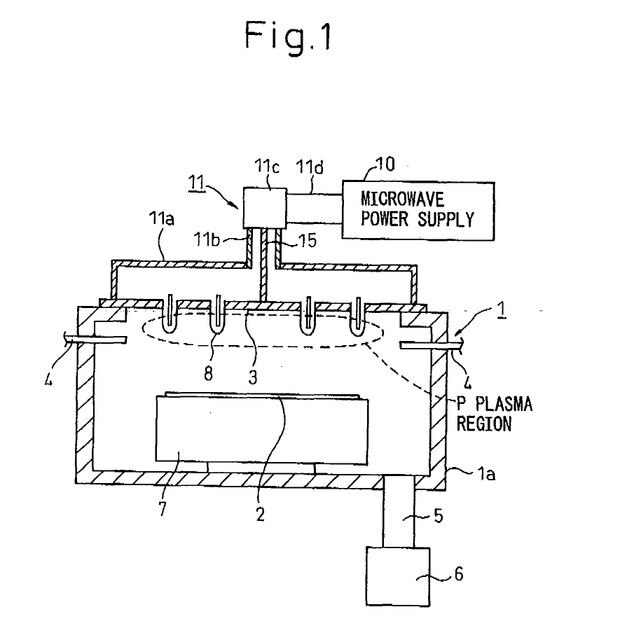

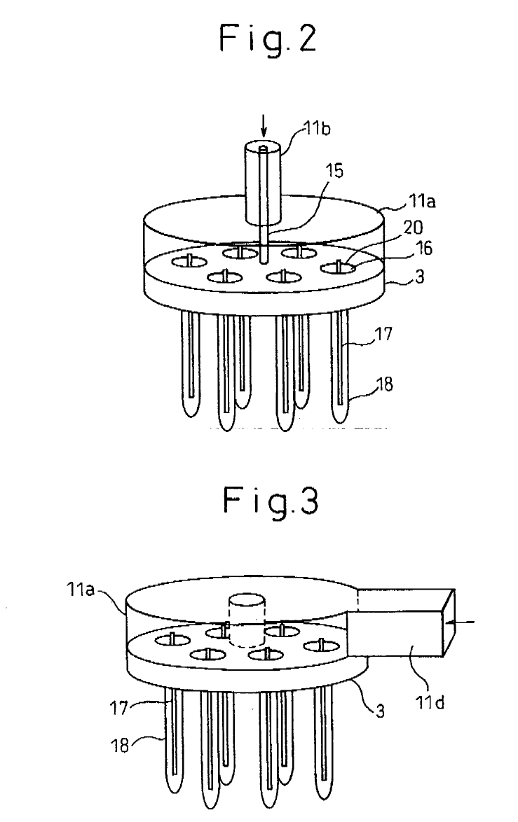

FIG. 1 is a schematic sectional view showing an embodiment of the constitution (or structure) of the plasma processing apparatus according to the present invention. FIG. 2 is a schematic perspective view for more specifically showing the embodiment of the antenna arrangement shown in FIG. 1.

Referring to FIGS. 1 and 2, the process chamber 1 as a vacuum container in such an embodiment is formed, e.g., so as to have a rectangular parallelepiped shape, in a case where a material for a liquid crystal device is to be treated. The process chamber 1 has a top plate 3 which is disposed opposite to an object 2 to be processed (such as wafer) via (or through the medium of) a region P in which the above-nentioned plasma is to be generated. In this embodiment, the top plate 3 is constituted by a metal-based or silicon-based material. The process chamber comprises the top plate 3 and a chamber wall 1a.

Further, a gas introduction pipe 4, for supplying to the inside of the process chamber 1 a gas such as process gas (e.g., a reactive gas for etching, a source gas for CVD (chemical vapor deposition)), and inert gas (e.g., Ar), is connected to the upper part of the process chamber 1. On the other hand, an exhaust pipe 5 for evacuating the process chamber 1 is connected to lower portion of the process chamber 1, and an exhaust pump 6 is connected to the exhaust pipe 5, and the process chamber 1 is maintained at a desired pressure by the action of the exhaust pump 6. The process chamber 1 may be formed not only into a rectangular parallelepiped shape, but also into a cylindrical or tubular shape.

In the process chamber 1, a substrate stage 7 is provided, and the above-mentioned object to be processed (such as wafer) 2 which is to be subjected to a treatment such as etching and CVD is placed on the substrate stage 7.

In this embodiment, the top plate 3 has a plurality of antennas 8 so that the antennas 8 penetrate the top plate 3 into the inside of the process chamber 1. In the present invention, it is sufficient that at least one antenna 8 is provided in the top plate 3.

Referring to FIGS. 1 and 2, a waveguide 11 is disposed on the top plate 3, and the waveguide 11 is connected to a microwave power supply 10 for generating microwaves at 2.45 GHz, for example. The waveguide 11 comprises a combination of: a coaxial cavity resonator 11a disposed adjacent to the top plate 3; a cylindrical waveguide 11b, one end of which is connected to the upper surface side of the coaxial cavity resonator 11a; a coaxial waveguide converter 11c connected to the upper surface side of the cylindrical waveguide 11b; and a rectangular waveguide 11d, one end of which is connected to the side surface of the coaxial waveguide converter 11c so as to provide a right angle therebetween, and the other end of which is connected to the microwave power supply 10.

In the present invention, a frequency region including UHF and microwaves is referred to as radio-frequency (or high-frequency) region. The radio-frequency power supplied from the radio-frequency power source may preferably have a frequency of not smaller than 300 MHz and not larger than 2500 MHz, which may include UHF having a frequency of not smaller than 300 MHz and microwave having a frequency of not smaller than 1 GHz. In the present invention, the plasma generated by the radio-frequency power is referred to as “radio-frequency plasma”.

In the inside of the above-mentioned cylindrical waveguide 11b, an axial portion 15 of an electroconductive material is coaxially provided, so that one end of the axial portion 15 is connected to the central (or nearly central) portion of the top plate 3, and the other end of the axial portion 15 is connected to the upper surface of the cylindrical waveguide 11b, whereby the cylindrical waveguide 11b constitutes a coaxial structure. As a result, the cylindrical waveguide 11b is constituted so as to function as a coaxial waveguide.

In the embodiment shown in FIG. 2, the microwaves propagating in the rectangular waveguide 11d, etc., from the microwave power supply 10 are distributed into plural voltage-drawing rods 17 disposed in a plurality of holes 16 which are provided in the resonator 11a. In general, the voltage-drawing rod 10a is protected by an insulating tube (a quartz tube, for example) 18, so that the voltage-drawing rod 17 does not contact the plasma directly. In addition, the process chamber 1 side is vacuum-sealed by the insulating tube is and an O-ring (not shown). Accordingly, the voltage-drawing rods 17 are supported with respect to the holes 16 by means of insulators 20 (for example, polytetrafluoroethylene). The voltage to be drawn to the voltage-drawing rods 17 may be changed depending on the height (degree of projection) of the voltage-drawing rod 17 in the resonator 11a.

In the embodiment of FIG. 2, the microwaves are propagated in the transmission line comprising the voltage-drawing rod 17 and the insulating tube 18. When the electric field strength in the insulating tube 18 reaches a threshold level on the outer wall surface of the insulating tube 18, plasma is ignited in the plasma-generating region P (FIG. 1) in the process chamber 1. The degrees of the distribution from the microwave waveguide line into the respective voltage-drawing rods 17 may be regulated depending on the height (degree of projection) of each rod 17 into the resonator 11a.

After plasma ignition, it is preferred to conduct matching by using a tuner (for example, stub tuner; not shown) as the variable capacity on the power supply side, so as to control the reflection electric power, whereby the reflection electric power is not returned to the power supply.

As shown in the schematic perspective view of FIG. 3, it is also possible to directly supply microwave power from the rectangular waveguide lid into the resonator 11a.

In addition, the voltage-drawing rod 17 can be cooled by circulating an insulating gas or insulating liquid in the clearance between the voltage-drawing rod 17 and the insulating tube 18.

As described hereinabove, when the plasma source having the above-mentioned constitution or structure is disposed in the process chamber 1, preferably having a metal-based or silicon-based top plate, uniform plasma corresponding to a large-diameter chamber can easily be obtained.

### Other Embodiments of an Antenna Arrangement

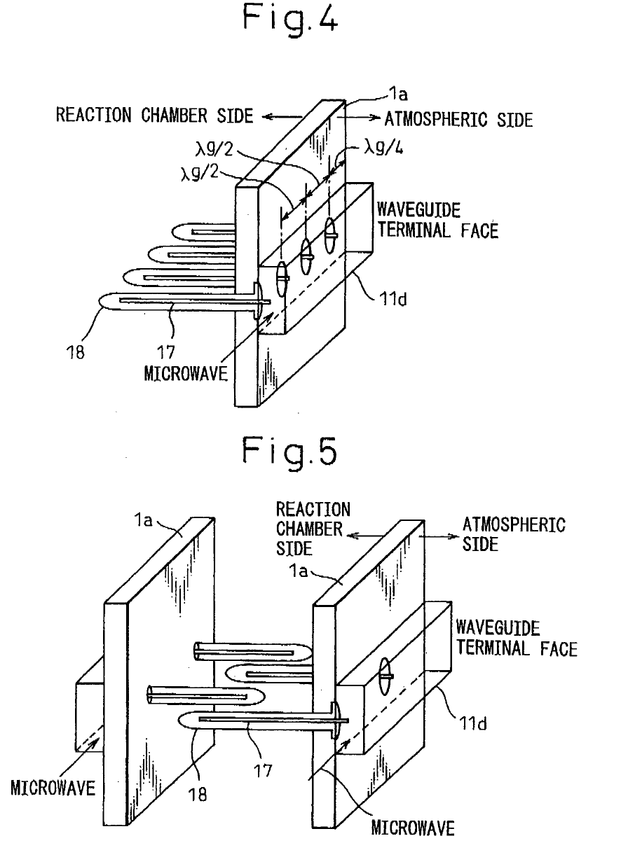

The schematic perspective view of FIG. 4 shows a second embodiment of the antenna arrangement. The constitution in the embodiment of this FIG. 4 is the same as that of FIG. 2 except that the antenna (electroconductive rod) is supported by the chamber wall 1a in a cantilever state.

Referring to the schematic perspective view of FIG. 4, another embodiment of the arrangement of plural antennas is described. In this embodiment, a transmission line comprising a voltage-drawing rod 17 and an insulating tube 18 penetrates a chamber wall 1a (instead of the tope plate 3), and is supported by the chamber wall 1a in a cantilever state. In view of the effective drawing of a high voltage, the position of the voltage drawing by the voltage-drawing rod 17 in the waveguide 11d may preferably be such that the position corresponds to {(1+2 m)/2}λg±(¼)λg (λg: guide wavelength; m: integer) from the terminal of the waveguide. When the guide wavelength in the waveguide is changed due to the absorption of plasma, for example, the drawing potential can be changed by finely adjusting the terminal face of the waveguide by use of a plunger.

The length, shape, arrangement form, etc., of the voltage-drawing rod 17 are not particularly limited, The thickness or diameter of the voltage-drawing rod 17 may be changed as desired, so as to change the degree of coupling with the plasma. Further, it is also possible to change the thickness or diameter of the voltage-drawing rod 17 as desired, so that the thickness or diameter is changed along the direction of microwave propagation.

The schematic perspective view of FIG. 5 shows a third embodiment of the antenna arrangement. The constitution in the embodiment of this FIG. 5 is the same as that of FIG. 4 except that the antennas (electroconductive rods) are respectively supported by the right and left chamber walls 1a in cantilever states.

### Embodiments of Chamber Wall Penetration

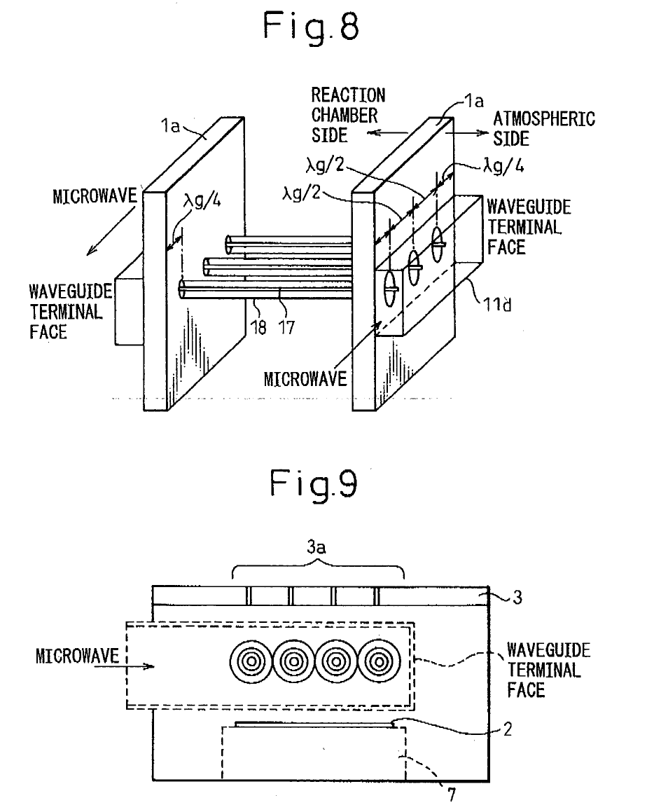

The schematic perspective views show some embodiments wherein an antenna is disposed so that the antenna penetrates the right and left chamber walls 1a. These embodiments have the same constitutions as those of the above-mentioned FIGS. 1-5 except that the antenna is disposed so as to penetrate the right and left chamber walls 1a. In addition, in the embodiment of FIG. 8, unlike in the embodiment of FIG. 7, the directions of the propagation of microwaves to be introduced from the right and left chamber walls are reversed to each other.

Such a “penetration” embodiment is advantageous in a point of view such that the deviation, or error, in the antenna position is reduced.

### Shower Head

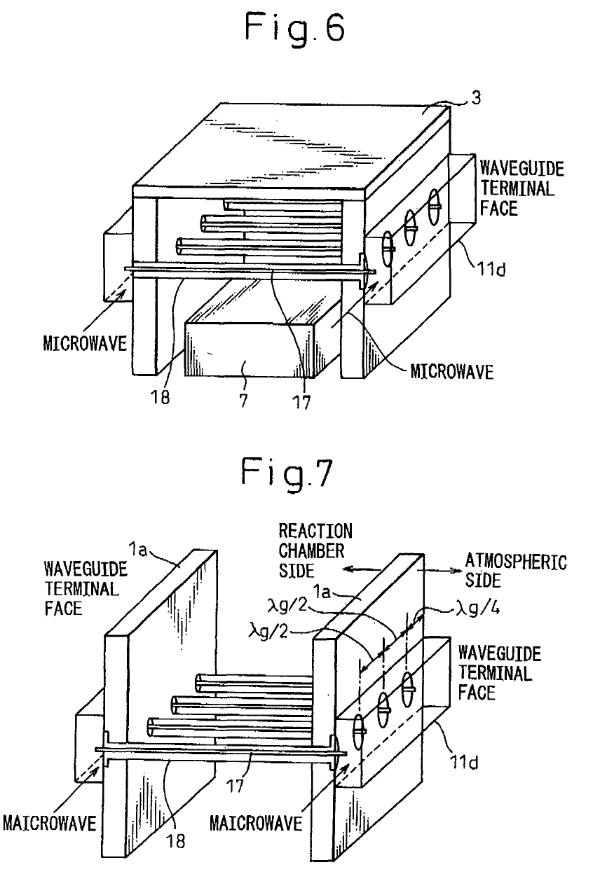

When the antenna is disposed as shown in the above-mentioned FIGS. 4-8 so that the antenna penetrates at least one of the chamber walls 1a, it is easy to cause the top plate 3 to have a “shower head” structure as shown in FIG. 9. Such an embodiment is advantageous in view of an improvement in the uniformity in the composition, concentration, etc., of a gas in the process chamber 1.

### Shapes of Top Plate

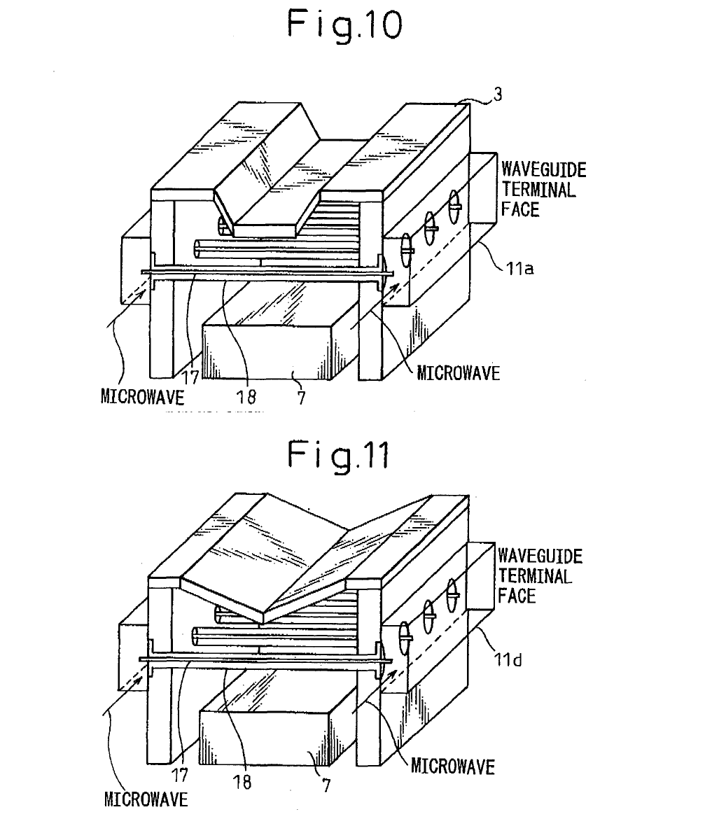

The schematic perspective views of FIGS. 10-13 show other embodiments of the shape of the top plate. In these figures, the shape of top plate 3 has been changed so as to impart a non-uniform distribution to the distance between the voltage-drawing rod 17 and the top plate 3 (with respect to the longitudinal direction of the voltage-drawing rod 17). It is also possible to constitute the shape of the top plate 3 in these Figuers. so that a non-uniform distribution is imparted between the respective elements constituting the array of the voltage-drawing rods 17 (in other words, a non-uniform distribution is imparted along the direction which is perpendicular to the longitudinal direction of the voltage-drawing rod 17).

Among the above-mentioned embodiments, as shown in FIG. 10 or FIG. 11, the central portion of the top plate 3 is protruded toward the inside of the chamber so that the distance between the top plate 3 and the voltage-drawing rod 17 in the central portion is smaller than that in the peripheral portion, whereby the capacitive coupling between the voltage-drawing rod 17 and the top plate 3 is enhanced, the electric field strength at the time of the ignition is enhanced, and the plasma-generating region is relatively limited, For example, in a case where an RIE (reactive ion etching) processing is intended, the bias distribution can be uniformized in a region of the top plate 3 facing the substrate surface.

In addition, as shown in a schematic perspective view of FIG, 11 the antennas are arranged so as to provide a distribution such that the central portion of the antenna is made nearer to the top plate 3, whereby the capacitive coupling between the voltage-drawing rod 17 and the top plate 3 is enhanced, the electric field strength at the time of the ignition is enhanced, and the plasma-generating region is relatively limited, in the same manner as in FIG. 10.

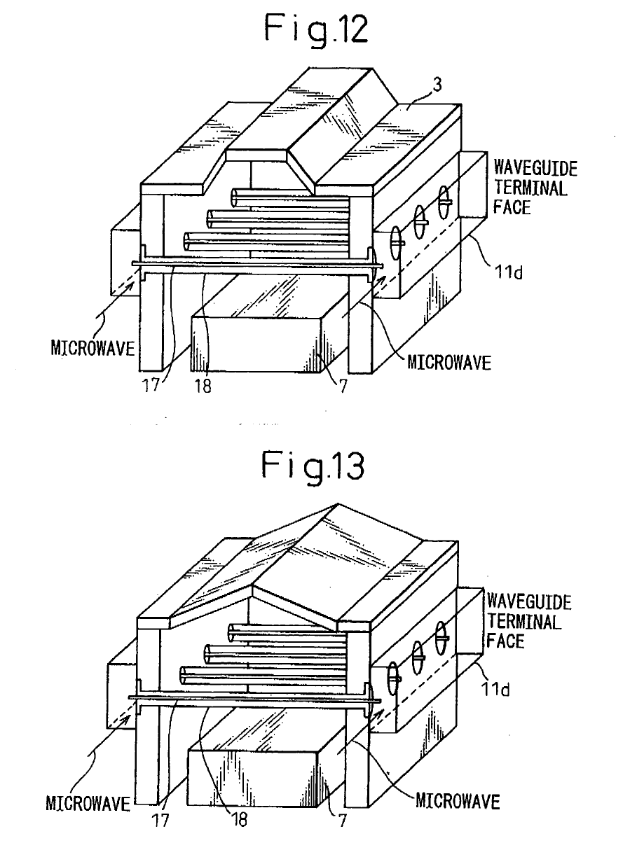

On the other hand, as shown in the schematic perspective view of FIG. 12, the central portion of the top plate 3 is raised so that the distance between the top plate 3 and the voltage-drawing rod 17 in the central portion is made larger than that in the peripheral portion thereof, whereby the capacitive coupling between the voltage-drawing rod 17 and the plasma at the peripheral portion is increased and, therefore, plasma is generated in the peripheral portion. For example, in a case where radical treatment is intended, plasma can be generated in the peripheral portion, and the processing on the substrate surface can be made uniform due to diffusion.

In addition, as shown in a schematic perspective view of FIG. 13, the voltage-drawing rods 17 are arranged so as to provide a distribution such that the distance between the central portion of the voltage-drawing rod 17 and the top plate 3 is larger than that in the peripheral portion thereof, whereby the capacitive coupling between the voltage-drawing rod 17 and the plasma at the peripheral portion is increased and, therefore, plasma can be generated in the peripheral portion.

### Change of Distance From Top Plate

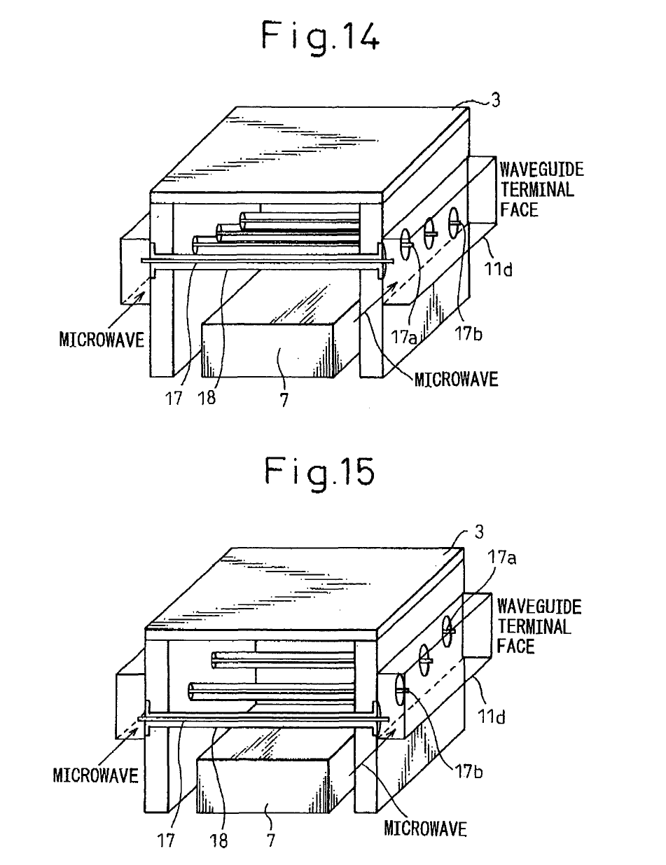

It is possible to change the distance between the respective voltage-drawing rods 17 and the top plate 3, as shown in the schematic perspective views of FIGS. 14 and 15. In such embodiments, depending on the distance between the top plate 3 and the respective voltage-drawing rods 17, it is possible that, for example, either one of these voltage-drawing rods 17a is used as a voltage-drawing rod for igniting the plasma, and the other of these voltage-drawing rods 17b is used as a voltage-drawing rod for maintaining a steady plasma

### Provision of Reflection-free Terminator

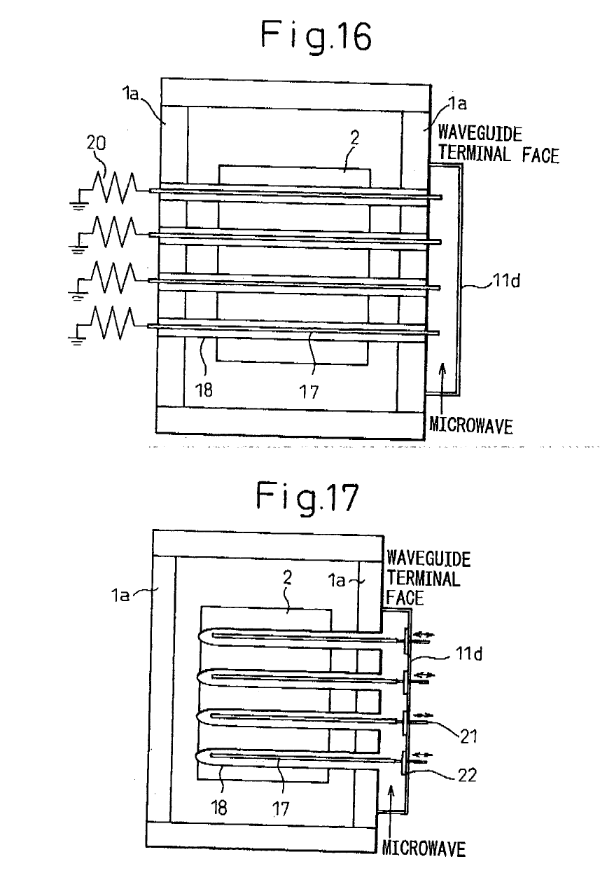

In the plasma processing apparatus according to the present invention, it is also possible to provide a reflection-free terminator 20 at the terminal of a transmission line for microwaves, as desired. The schematic sectional view of FIG. 16 shows an embodiment of such a constitution.

In FIG. 16, a plurality of voltage-drawing rods 17 are arranged in the process chamber 1 so that they penetrate the chamber walls 1a disposed opposite to each other and, further, reflection-free terminators 20 are provided at the terminal of the voltage-drawing rods 17.

### Embodiment Wherein Antenna is Movable

The location or position of each voltage-drawing rod 17 can also be movable or changeable, depending on a certain condition such as process gas, pressure, and electric power. The schematic plan views of FIGS. 17 to 20 show examples of such an embodiment. In these embodiments, for example, a tuner 21, of which the position is controllable by using an external action, is provided while being supported by an insulating insulator 22, the tuner 21 being driven as desired so as to change the position of the voltage-drawing rod 17, whereby the plasma distribution in the process chamber 1 can be changed.

In this case, it is possible that, for example, an electroconductive jig (not shown) supported by an insulating insulator 22 is provided between thee voltage-drawing rod 17 (electroconductive rod) and the insulating insulator 22, so that the jig is always caused to contact the voltage-drawing rod 17 so as to provide a low resistance therebetween, while being slidably supported by the voltage-drawing rod 17 in a multi-contact manner, etc.

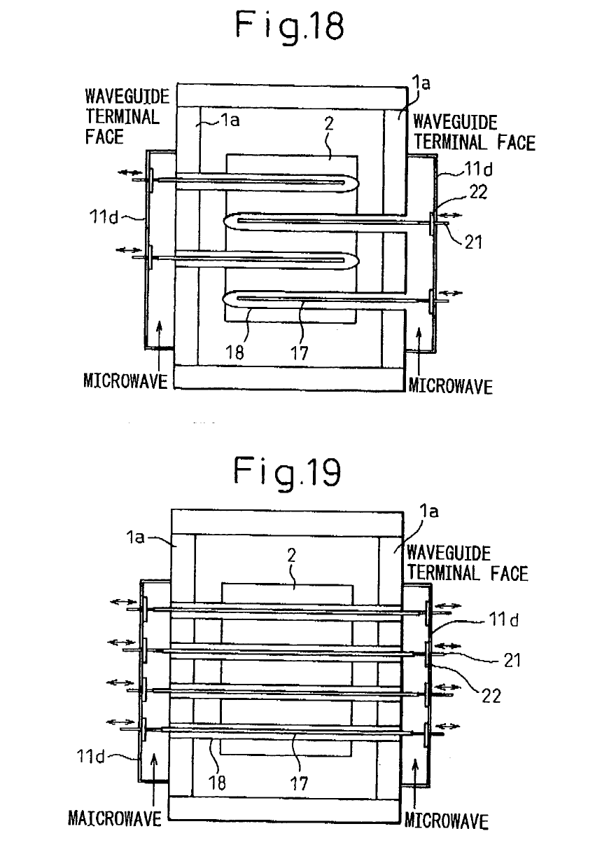

The embodiment shown in FIG. 18 has the same constitution as that of the above-mentioned FIG. 17 except that the insulating tube 18 is disposed so that insulating tube 18 is supported with respect to the right and left chamber walls 1a in a cantilever manner.

The embodiment shown in FIG. 19 has the same constitution as that of the above-mentioned FIG. 17 except that the insulating tube 18 is provided so that the insulating tube 18 penetrates the right and left chamber walls 1a.

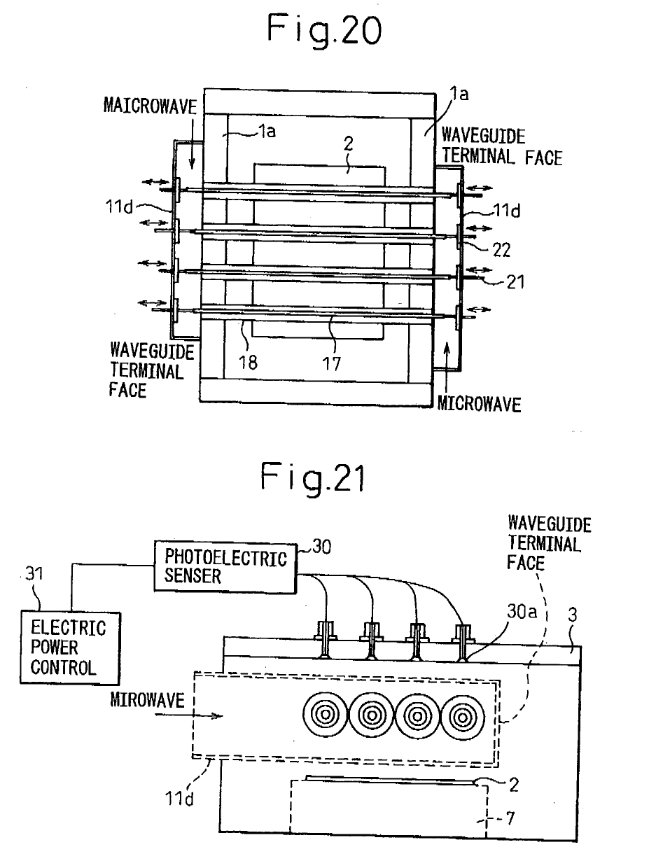

The embodiment shown in FIG. 20 has the same constitution as that of the above-mentioned FIG. 19 except that the directions of the microwave introduction, in the right and left sides in FIG. 20, are opposite to each other.

### Provision of Sensor

Depending on certain conditions such as process gas, pressure, and electric power, the distribution ratio of the electric power to be supplied to each voltage-drawing rod 17 can be changed, and the resultant plasma may become non-uniform. In such a case, it is possible that the distribution of the plasma density is externally monitored during plasma generation, as desired, by using a photoelectric sensor, etc., and the results of the sensor monitoring are fed back to a variable tuner 21. In this case, it is possible that the degrees of coupling of the respective voltage-drawing rods 17 and the microwave transmission line 11 are regulated on the basis of the above monitoring, whereby the plasma distribution can be uniform over the entire region.

FIG. 21 shows an example of such an embodiment. In this embodiment, a photoelectric sensor 30 having a photodetector portion 30a is provided to the top plate 3 of chamber 1. The photoelectric sensor 30 is further connected to an electric power control unit 31, and the above-mentioned variable tuner 21 can be controlled on the basis of the signal from the electric power control unit 31.

In this case, for example, the coupling between the microwave transmission line 11 and the voltage-drawing rod 17 can be strengthened by regulating the capacity of the tuner 21 so as to supply electric power to the voltage-drawing rod 17. On the contrary, the coupling between the microwave transmission line 11 and the voltage-drawing rod 17 can also be weakened by regulating the capacity of the tuner 21. It is also possible that a library is preliminarily prepared with respect to each of process conditions so that the condition (capacity of the tuner) can provide a uniform plasma, and the capacity of the tuner is regulated in such a manner after plasma ignition.

In this case, when the number of the voltage-drawing rods 17 is relatively large, the sensors and the voltage-drawing rods 17 are subjected to grouping, and the capacity of the tuners may be regulated corresponding to each of the resultant groups. Further, it is also possible that the outputs of the photoelectric sensor are converted into the distribution or uniformity of plasma, or distribution or rate of the process (such as etching and CVD) by using a database or a theoretical formula, and the tuner is controlled so as to provide desired results.

### Provision of Partial Opening on Ground Line

In the present invention, as desired, it is possible that an opening is provided with respect to at least a part of the ground line 32 in the process chamber 1, and the microwave electric field is externally emitted from the opening portion 32a so as to generate plasma in the process chamber 1, whereby the plasma distribution is regulated by using the position of the opening portion 32a. On the basis of such regulation of the plasma distribution, a desired plasma distribution can be obtained more easily.

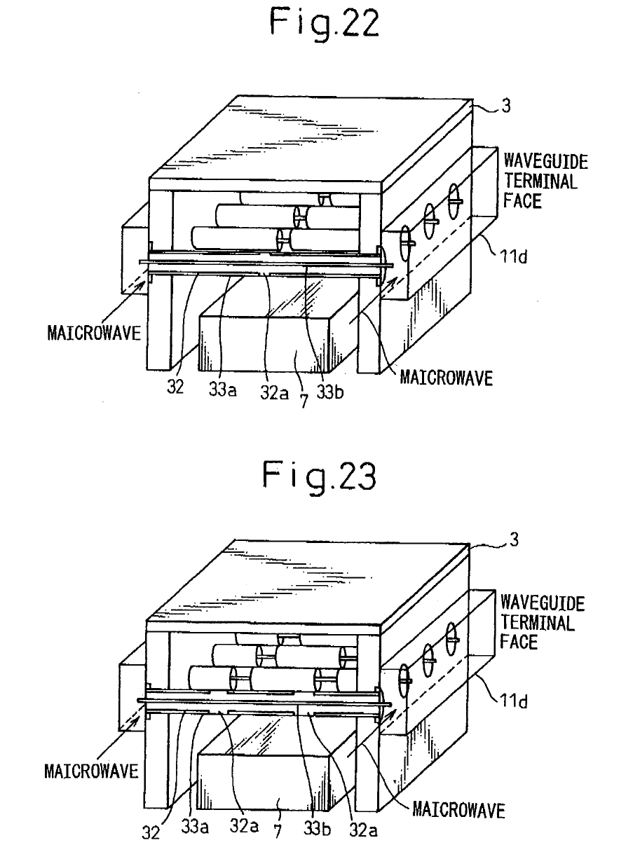

The schematic perspective views of FIG. 22 and FIG. 23 show an example of such an embodiment. In these figures, the ground line 32 is usually constituted by a coaxial line. Referring to FIG. 22, the ground line 32 of the transmission line in the process chamber 1 is constituted by a coaxial line which comprises a core wire 33b, and the inner wall of an electroconductive tube, or an insulating tube 33a of which the outside is covered with plating. When the covering or coating of the ground line 32 is removed with respect to a part of the coaxial line, the resultant opening portion 32a provides a high impedance in view of the impedance, so that the voltage is elevated. A strong electric field can be generated by the resultant high potential so as to ignite a plasma. In addition, the microwave energy is supplied from the opening portion 32a, and the plasma begins to spread outward from this point depending on an increase in the electric power. In other words, it is possible to determine the position of this opening portion 32a so that it can provide a desired plasma distribution.

The constitution of FIG. 23 is the same as that of FIG. 22 except the above-mentioned two opening portions 32a are provided with respect to the transmission line in the chamber.

As described hereinabove, the present invention can provide a plasma processing apparatus which can generate high-density plasma with a high efficiency, even in the case of the treatment of an object having a large area.

From the invention thus described, it will be obvious that the invention may be varied in many ways. Such variations are not to be regarded as a departure from the spirit and scope of the invention, and all such modifications as would be obvious to one skilled in the art are intended to be included within the scope of the following claims.

The present application is based on Japanese priority application No. 2002-207310 filed on Jul. 16, 2002, the entire con tents of which are hereby incorporated by reference.

What is claimed is:

1. A plasma processing apparatus for supplying microwaves into a process chamber so as to generate plasma, to thereby treat an object to be processed with the plasma;
wherein the process chamber has a top plate which is disposed opposite to the object to be processed, through the medium of a region for generating the plasma; and the top plate has at least one antenna which is disposed so that the antenna penetrates the top plate into the inside of the process chamber.

2. A plasma processing apparatus according to claim 1, wherein the antenna comprises a voltage-drawing rod for drawing a voltage from a waveguide or resonator disposed outside of the process chamber; and an insulating material surrounding the voltage-drawing rod.

3. A plasma processing apparatus according to claim 1, wherein at least one antenna is disposed in the. process chamber, so as to provide a linear and/or curved line.

4. A plasma processing apparatus according to claim 2, wherein the position of the voltage drawing of the voltage-drawing rod 17 in the waveguide corresponds to {(1+2 m)/2}λg±(¼)λg (λg: guide wavelength; m: integer) from the terminal of the waveguide.

5. A plasma processing apparatus according to claim 2, wherein the thickness or diameter of the voltage-drawing rod disposed in the process chamber is changed along the propagation direction of the microwaves.

6. A plasma processing apparatus according to claim 2, which has a tuner for changing the degree of the protrusion of the voltage-drawing rod into the waveguide or resonator.

7. A plasma processing apparatus according to claim 2, which has a mechanism for moving the voltage-drawing rod per se so that the coupling between the plasma and the waveguide or resonator is variable.

8. A plasma processing apparatus according to claim 2, wherein an insulating fluid is circulated between the voltage-drawing rod and the insulating material.

9. A plasma processing apparatus according to claim 2, which has a mechanism for variably changing the distance between the top plate and the voltage-drawing rod.

10. A plasma processing apparatus according to claim 1, wherein a measuring device is disposed in at least one position of the top plate so as to monitor the state of the generated plasma.

11. A plasma processing apparatus according to claim 1, wherein the top plate has a plurality of holes for passing a gas to be supplied to the process chamber.

12. A plasma processing apparatus according to claim 1, wherein a susceptor for supporting the object to be processed is disposed in the process chamber, and a bias is applicable to the susceptor.

13. A plasma processing apparatus according to claim 1, wherein at least a portion of the ground line in the process chamber has an opening, and the plasma is generated due to the radiation of a microwave electric field from the opening toward the outside of the ground line.

14. A plasma processing apparatus for supplying microwaves into a process chamber so as to generate plasma, to thereby treat an object to be processed with the plasma;
wherein the process chamber comprises a top plate and a chamber wall for defining the process chamber; and the chamber wall has at least one antenna so that the antenna penetrates the chamber wall into the inside of the process chamber; and the antenna is disposed in the inside of the process chamber with respect to the top plate.

15. A plasma processing apparatus according to claim 14, wherein the antenna comprises a voltage-drawing rod for drawing a voltage from a waveguide or resonator disposed outside of the process chamber; and an insulating material surrounding the voltage-drawing rod.

16. A plasma processing apparatus according to claim 14, wherein at least one antenna is disposed in the process chamber, so as to provide a linear and/or curved line.

17. A plasma processing apparatus according to claim 15, wherein the position of the voltage drawing of the voltage-drawing rod 17 in the waveguide corresponds to {(1+2 m)/2}λg±(¼)λg (λg: guide wavelength; m; integer) from the terminal of the waveguide.

18. A plasma processing apparatus according to claim 2, wherein the thickness or diameter of the voltage-drawing rod disposed in the process chamber is changed along the propagation direction of the microwaves.

19. A plasma processing apparatus according to claim 15, which has a tuner for changing the degree of the protrusion of the voltage-drawing rod into the waveguide or resonator.

20. A plasma processing apparatus according to claim 15, which has a mechanism for moving the voltage-drawing rod per se so that the coupling between the plasma and the waveguide or resonator is variable.

21. A plasma processing apparatus according to claim 2, wherein an insulating fluid is circulated between the voltage-drawing rod and the insulating material.

22. A plasma processing apparatus according to claim 15, which has a mechanism for variably changing the distance between the top plate and the voltage-drawing rod.

23. A plasma processing apparatus according to claim 14, wherein a measuring device is disposed in at least one position of the top plate so as to monitor the state of the generated plasma.

24. A plasma processing apparatus according to claim 14, wherein the top plate has a plurality of holes for passing a gas to be supplied to the process chamber.

26. A plasma processing apparatus according to claim 14, wherein a susceptor for supporting the object to be processed is disposed in the process chamber, and a bias is applicable to the susceptor.

27. A plasma processing apparatus according to claim 14, wherein at least a portion of the ground line in the process chamber has an opening, and the plasma is generated due to the radiation of microwave electric field from the opening toward the outside of the ground line.

28. A plasma processing apparatus for supplying microwave into a process chamber so as to generate plasma, to thereby treat an object to be processed with the plasma;
wherein the process chamber has a top plate which is disposed opposite to the object to be processed through the medium of a region for generating the plasma; and the top plate comprises a metal-based or silicon-based material.

29. A plasma processing apparatus according to claim 28, wherein the antenna comprises a voltage-drawing rod for drawing a voltage from a waveguide or resonator disposed outside of the process chamber; and an insulating material surrounding the voltage-drawing rod.

30. A plasma processing apparatus according to claim 28, wherein at least one antenna is disposed in the process chamber, so as to provide a linear and/or curved line.

31. A plasma processing apparatus according to claim 29, wherein the position of the voltage drawing of the voltage-drawing rod 17 in the waveguide corresponds to {(1+2 m)/2}λg±(¼)λg (λg: guide wavelength; m: integer) from the terminal of the waveguide.

32. A plasma processing apparatus according to claim 29, wherein the thickness or diameter of the voltage-drawing rod disposed in the process chamber is changed along the propagation direction of the microwave.

33. A plasma processing apparatus according to claim 29, which has a tuner for changing the degree of the protrusion of the voltage-drawing rod into the waveguide or resonator.

34. A plasma processing apparatus according to claim 29, which has a mechanism for moving the voltage-drawing rod per se so that the coupling between the plasma and the waveguide or resonator is variable.

35. A plasma processing apparatus according to claim 29, wherein an insulating fluid is circulated between the voltage-drawing rod and the insulating material.

36. A plasma processing apparatus according to claim 29, which has a mechanism for variably changing the distance between the top plate and the voltage-drawing rod.

37. A plasma processing apparatus according to claim 28, wherein a measuring device is disposed in at least one position of the top plate so as to monitor the state of the generated plasma.

38. A plasma processing apparatus according to claim 28, wherein the top plate has a plurality of holes for passing a gas to be supplied to the process chamber.

39. A plasma processing apparatus according to claim 28, wherein a susceptor for supporting the object to be processed is disposed in the process chamber, and a bias is applicable to the susceptor.

40. A plasma processing apparatus according to claim 28, wherein at least a portion of the ground line in the process chamber has an opening, and the plasma is generated due to the radiation of microwave electric field from the opening toward the outside of the ground line.
